(19) United States
(12) Patent Application Publication
(10) Pub. No.: US 2026/0319028 A1
(43) Pub. Date: Oct. 15, 2026

(54) SENSOR APPARATUS AND METHOD FOR OPERATING A SENSOR APPARATUS

(71) Applicant: Robert Bosch GmbH, Stuttgart (DE)

(72) Inventor: Tsung-I Yin, Tuebingen (DE)

(21) Appl. No.: 19/473,678

(22) PCT Filed: Jul. 4, 2024
(86) PCT No.: PCT/EP2024/068804

§ 371 Date: Oct. 8, 2025

(30) Foreign Application Priority Data
Jul. 27, 2023 (DE) 10 2023 207 203.3

(51) Int. Cl. G01R 33/028; G01R 33/02; G01R 33/09

(52) U.S. Cl. CPC G01R 33/0286; G01R 33/0206; G01R 33/093

(57) ABSTRACT

A sensor element for three-dimensionally sensing a magnetic field using magnetoresistive sensor elements. The sensor apparatus includes at least one arrangement with four magnetoresistive sensor elements in the form of a Wheatstone bridge which can be deflected using a microelectromechanical structure so that a mechanical force is applied to the sensor elements.

### FIELD

The present invention relates to a sensor apparatus and to a method for operating a sensor apparatus. The present invention relates in particular to a sensor apparatus having magnetoresistive sensor elements.

### BACKGROUND INFORMATION

Magnetic field sensors are used to sense magnetic fields. So-called magnetoresistive sensors, inter alia, are used for this purpose. These take advantage of the fact that an electrical resistance in a particular material can change according to an external magnetic field. Moreover, the resistance can also change due to a mechanical force (tensile force or compressive force) on the sensor element. One such effect is known as the magnetoelastic effect.

Germany Patent Application No. DE 102 36 983 A1 describes, for example, a magnetic sensor arrangement with a magnetic-field-sensitive sensor layer in an integrated multi-layer system, wherein the electrical resistance changes according to an external magnetic field.

### SUMMARY

The present invention provides a sensor apparatus and a method for operating a sensor apparatus. Advantageous embodiments of the present invention are disclosed herein.

According to an example embodiment of the present invention, provided is therefore:

A sensor apparatus having a microelectromechanical structure (MEMS) and having at least one sensor device. The MEMS is designed to apply a tensile force as well as a compressive force to the at least one sensor device. Each of the at least one sensor device comprises four magnetoresistive sensor elements. In each of the at least one sensor device, the four sensor elements are arranged in the form of a Wheatstone bridge. Accordingly, a first magnetoresistive sensor element is arranged between a positive voltage supply terminal and a first node point. A second magnetoresistive sensor element is arranged between the first node point and a negative voltage supply terminal. A third magnetoresistive sensor element is arranged between a positive voltage supply terminal and a second node point. A fourth magnetoresistive sensor element is arranged between the second node point and the negative voltage supply terminal. The reference magnetic field directions of the first, second, third and fourth sensor elements of a sensor device are oriented identically. The preferred directions of the first and third sensor elements of a sensor device are oriented oppositely to the preferred directions of the second and fourth sensor elements of said sensor device. Furthermore, the reference magnetic field directions and the preferred directions of all the sensor elements of the at least one sensor device lie in a common predetermined plane.

According to an example embodiment of the present invention, provided is furthermore:

A method for operating a sensor apparatus, in particular a sensor apparatus according to the present invention. The method comprises a step for sensing a first voltage between the first node point and the second node point of the at least one sensor device while a compressive force is applied to the at least one sensor device by the microelectromechanical structure. In a further step, a second voltage is sensed between the first node point and the second node point of the at least one sensor device while a tensile force is applied to the at least one sensor device by the microelectromechanical structure. The method also comprises a step for ascertaining a value of a magnetic field strength using the sensed first and second voltages.

Magnetoresistive sensors are capable of ascertaining, on the basis of a change in electrical resistance according to an applied magnetic field, a value of the electric field strength of the applied magnetic field. The magnetoresistive sensors may define a plane which is spanned by the orientation of the preferred direction (easy axis) and of the reference magnetic field direction (pinning direction) of the sensors. The applied magnetic field may have magnetic field components which run parallel to this plane (in-plane components) and magnetic field components which run perpendicularly to this plane (out-of-plane components).

Identifying the components of a magnetic field vector is a challenge. In particular, it is desirable to ascertain the individual components of a magnetic field vector as simultaneously as possible. This enables the realization a 3-axis sensor as a single integrated component.

The present invention makes use of the fact that magnetoresistive sensor elements have not only a variation in electrical resistance according to an applied magnetic field but also a variation in electrical resistance according to an applied tensile or compressive force. By specific application of tensile and compressive forces to the sensor elements, the present invention allows the sensor signals ascertained by the magnetoresistive sensor elements to be evaluated in order to simultaneously sense an external magnetic field and an external force and to determine the magnetic field and the force independently of one another. On the basis of this, it is also possible to create a sensor apparatus in order to realize three-dimensional sensing of a magnetic field. In particular, the individual spatial directions of a magnetic field in three-dimensional space can be determined by means of a single monolithic sensor.

According to an example embodiment of the present invention, for the sensing of the magnetic field, at least one sensor device is provided in which four magnetoresistive sensor elements are arranged in the form of a Wheatstone bridge. The reference magnetic field directions (pinning direction) and the initial preferred directions (easy axis) of all the sensor elements lie in a common plane, and the initial preferred directions of all the sensor elements are also oriented identically. The reference magnetic field directions of diagonally opposite sensor elements are likewise oriented identically, while two sensor elements connected in series have, in each case, opposite reference magnetic field directions.

These sensor devices may be deflected perpendicularly to the common plane described above by means of a microelectromechanical system (MEMS). In this way, a tensile or compressive force may be applied to the individual sensor elements.

By evaluating the voltages at the two node points of the individual sensor devices in combination with the known deflection and the associated force applied to the sensor elements, it is subsequently possible to separate the individual components of the magnetic field in the predetermined plane and perpendicular to the predetermined plane. In this way, the magnetic field components for the individual spatial directions may be ascertained individually.

According to one example embodiment of the present invention, the sensor apparatus comprises multiple sensor devices. The multiple sensor devices may be divided into at least two groups. A first group of sensor apparatuses comprises at least one sensor device. Likewise, a second group of sensor devices comprises at least one sensor device. The sensor elements in the two groups of sensor apparatuses are arranged such that the preferred directions of the sensor elements of the first group of sensor devices are oriented perpendicularly to the preferred directions of the second group of sensor devices. In this way, mutually orthogonal components of the magnetic field can be determined by the two groups of sensor devices in the predetermined plane described above.

According to one example embodiment of the present invention, the first group of sensor devices comprises two sensor devices. Likewise, the second group of sensor devices comprises two sensor devices. The four sensor elements may be arranged, for example, at vertices of a virtual rectangle or of a virtual diamond, in particular of a square. In this case, the two sensor elements of each group are arranged diagonally opposite. In this way, a particularly advantageous arrangement of the sensor devices can be achieved.

According to one example embodiment of the present invention, the microelectromechanical structure comprises a coil. The windings of the coil may, for example, be arranged in the predetermined plane described above. The coil may be designed to deflect the microelectromechanical structure with the at least one sensor device in a direction perpendicular to the predetermined plane. In this way, an easily controllable deflection of the sensor devices for application of a tensile or compressive force can be achieved.

According to one example embodiment of the present invention, the coil comprises a ferromagnetic element. As a result of such a ferromagnetic element, the deflection or the force exerted by the current-carrying coil can be increased.

According to one example embodiment of the present invention, the sensor apparatus comprises a processing device. The processing device may be designed to sense a voltage between the first node point and the second node point of the at least one sensor device. Furthermore, the processing device may ascertain a value of a magnetic field strength using the sensed voltage or the sensed voltages. Optionally, an external force on the sensor apparatus, in particular on the sensor elements, may also be ascertained using the voltages.

According to one example embodiment of the present invention, the processing device is designed to ascertain individual values of the magnetic field strength for mutually orthogonal spatial directions. In particular, values of the magnetic field strength parallel to the predetermined plane described above and perpendicular to that predetermined plane can be ascertained. In the case of multiple sensor devices which are differently oriented, multiple (two) components of the magnetic field strength in this plane can also be ascertained.

According to one example embodiment of the present invention, the processing device is designed to control the microelectromechanical structure. This may be done, for example, by applying a defined current to a coil in the MEMS.

According to one example embodiment of the present invention, the processing device is implemented as an application-specific integrated circuit (ASIC) in the sensor apparatus. For example, such an integrated circuit may be implemented directly in a substrate coupled to the MEMS.

The above configurations and further developments can be combined with one another in any desired manner if useful. Further configurations, developments and implementations of the present invention also include not explicitly mentioned combinations of features of the present invention described above or in the following with respect to the embodiment examples. Those skilled in the art will in particular also add individual aspects as improvements or additions to the respective basic forms of the present invention.

### BRIEF DESCRIPTION OF THE DRAWINGS

Further features and advantages of the present invention are explained in the following with reference to the figures.

FIGS. 1A, 1B show schematic illustrations of the resulting angles and directions in sensor elements for a sensor apparatus according to one example embodiment of the present invention.

FIG. 2 shows a schematic illustration of a sensor device for a sensor apparatus according to one example embodiment of the present invention.

FIGS. 3A, 3B, 3C show diagrams for illustrating the relationships between voltage at the sensor devices and the magnetic fields or mechanical forces.

FIG. 4 shows a schematic illustration of a cross-section through a sensor apparatus 1 according to one example embodiment of the present invention.

FIG. 5 shows a schematic illustration of a cross-section through a sensor apparatus according to another example embodiment of the present invention.

FIG. 6 shows a schematic illustration of a possible arrangement of sensor devices in a sensor apparatus according to one example embodiment of the present invention.

FIG. 7 shows a flowchart which forms the basis of a method for operating a sensor apparatus according to another example embodiment of the present invention.

### DETAILED DESCRIPTION OF EXAMPLE EMBODIMENTS

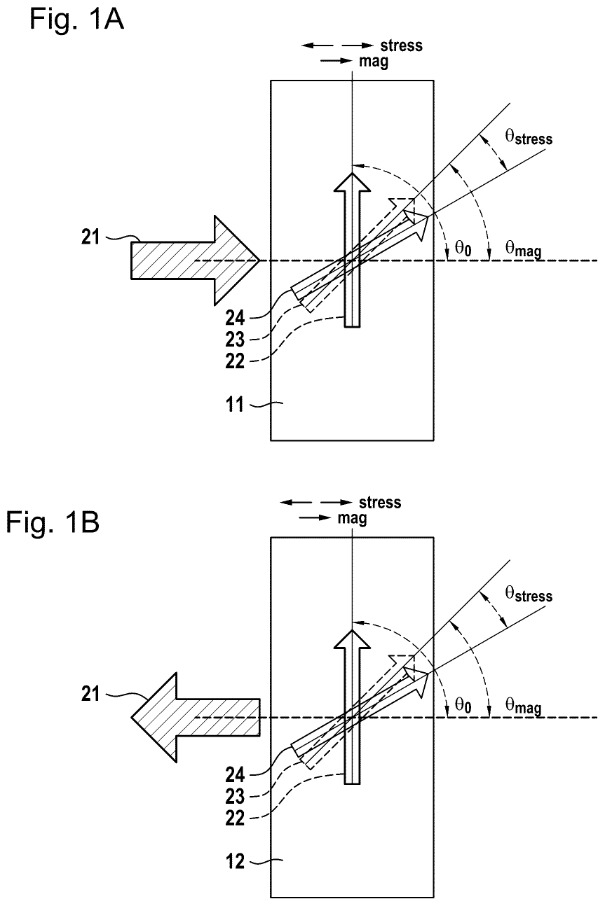

FIG. 1A shows a schematic illustration of a magnetoresistive sensor element 11 according to one embodiment. Here, the magnetization direction of the reference layer (pinning direction) is marked with the arrow 21. This direction is hereinafter referred to as the reference magnetic field direction.

The initial magnetization direction of the free layer is hereinafter referred to as the preferred direction (“easy axis”) and is shown with the arrow 22. When an external magnetic field is applied, this results in a magnetization, shown with the arrow 23, in the free layer. When a mechanical force is applied, this results in a magnetization, shown with the arrow 24, in the free layer.

The resulting electrical resistance R1 thus results from the following formula:

$$R 1 = R ( θ 0 ) - \frac{Δ R}{2} cos ( θ mag - θ stress )$$

Here, R(θ0) refers to the resistance of the sensor element under the influence of an external magnetic field or an external force. ΔR describes the difference between the maximum value and the minimum value of the electrical resistance. The angles θ0, θmag and θstress are shown in FIG. 1A and denote the angle between the reference magnetic field direction and the preferred direction, the angle between the reference magnetic field direction and the magnetization when an external magnetic field is applied, and the angle between the reference magnetic field direction and the magnetization when an external force is applied.

FIG. 1B shows a schematic illustration of a magnetoresistive sensor element 12 according to one embodiment. The configuration according to FIG. 1B differs from the above-described configuration according to FIG. 1A in that the reference magnetic field direction is rotated by 180°, i.e., oriented oppositely. Thus, the following results for the resulting electrical resistance R2 in this configuration:

$$R 2 = R ( θ 0 ) - \frac{Δ R}{2} cos ( ( 180 ° - θ mag ) + θ stress )$$

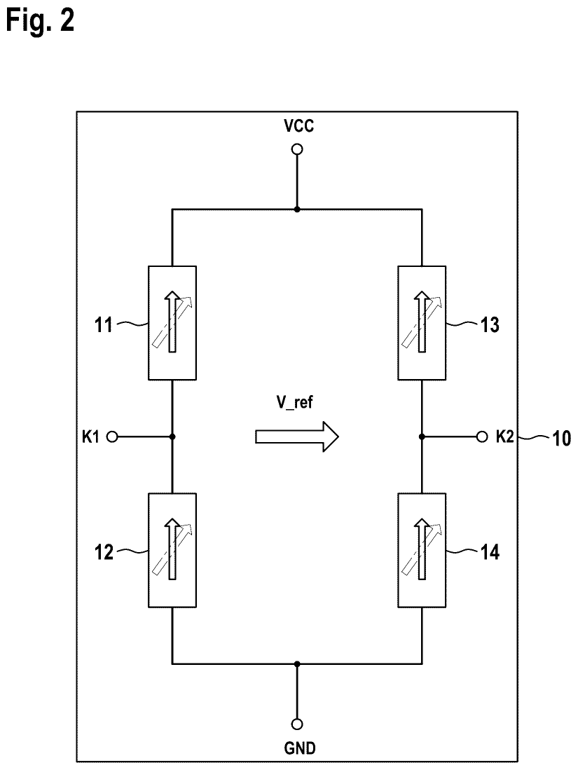

FIG. 2 shows a schematic illustration of a sensor device 10 having four sensor elements 11 to 14 according to one embodiment. A first sensor element 11 is arranged between a terminal for a positive supply voltage VCC and a first node point K1. A second sensor element 12 is arranged between the first node point K1 and a terminal for a negative supply voltage or a reference potential GND. Parallel thereto, a third sensor element 13 is arranged between the terminal for the positive supply voltage VCC and a second node point K2. A fourth sensor element 14 is arranged between the second node point K2 and the terminal for the negative supply voltage or the reference potential GND. Such a circuit configuration is known as the Wheatstone bridge, for example.

The first sensor element 11 and the fourth sensor element 14 are oriented according to the configuration in FIG. 1A. The second sensor element 12 and the third sensor element 13 are oriented according to the configuration in FIG. 1B.

Thus, for the first sensor element 11 and the fourth sensor element 14, an electrical resistance of R1=R0−ΔRmag results. For the second and third sensor elements 12, 13 an electrical resistance of R2=R0+ΔRmag results. Thus, without an external mechanical force, a reference voltage V_ref corresponding to the external magnetic field arises between the second node point K2 and the first node point K1.

When an external tensile force is applied to the sensor elements 11 to 14 of the sensor device 10, a value of R1=R0−ΔRmag−ΔRstress results for the electrical resistance R1 of the first and fourth sensor elements 11, 14. Correspondingly, a value of R2=R0−ΔRmag+ΔRstress results for the electrical resistance R2 of the second and third sensor elements 12, 13. The voltage between the second node point K2 and the first node point K1 is hereinafter referred to as V1.

When an external compressive force is applied to the sensor elements 11 to 14 of the sensor device 10, a value of R1=R0−ΔRmag+ΔRstress results for the electrical resistance R1 of the first and fourth sensor elements 11, 14. Correspondingly, a value of R2=R0−ΔRmag−ΔRstress results for the electrical resistance R2 of the second and third sensor elements 12, 13. The voltage between the second node point K2 and the first node point K1 is hereinafter referred to as V2.

Thus, when a corresponding force is applied to the sensor device 10, the voltage between the second node point K2 and the first node point K1 also changes. Since tensile force and compressive force change the voltage between the two node points K2 and K1 in the same way but with opposite signs, an external mechanical force and a magnetic field can be simultaneously ascertained by means of such an arrangement.

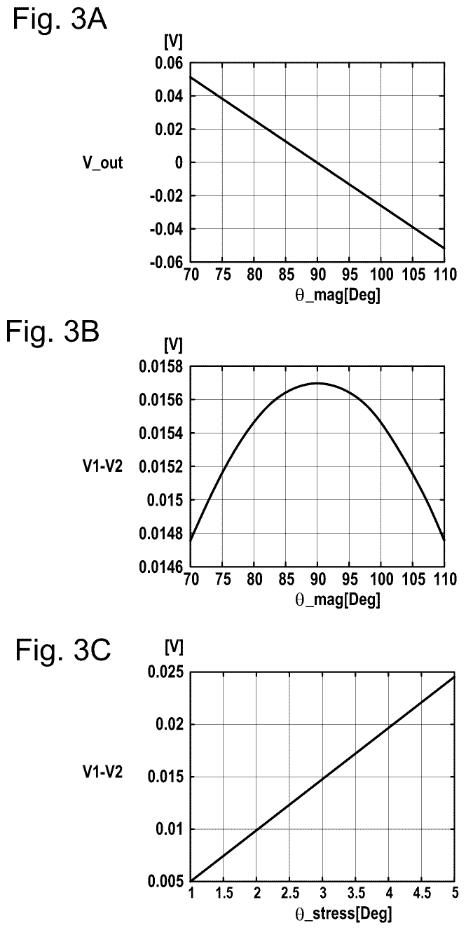

FIG. 3A shows a graph illustrating the dependence between the measured output voltage V_out at the node points K2-K1 and the direction of the resulting angle θmag. The output voltage V_out shown here corresponds to the average value of the voltage V1 when a compressive force is applied and the voltage V2 when a tensile force is applied: V_out=(V1+V2)/2.

FIG. 3B shows a graph illustrating the relationship between a difference between the voltages V1−V2 described above in connection with FIG. 2 and the direction of the resulting angle θmag.

FIG. 3C shows a graph illustrating the relationship between a difference between the voltages V1−V2 described above in connection with FIG. 2 and the direction of the resulting angle θstress. For this purpose, a fixed angle θmag of 70 degrees was assumed.

According to the relationships shown in FIGS. 3A-3C, a good linear relationship between the output voltage at the first and second node points K1, K2 and the mechanical force can be recognized. On the basis of the simulated relationships shown, it is thus possible to sense an external magnetic field and a mechanical force simultaneously and to consider the two effects independently of one another.

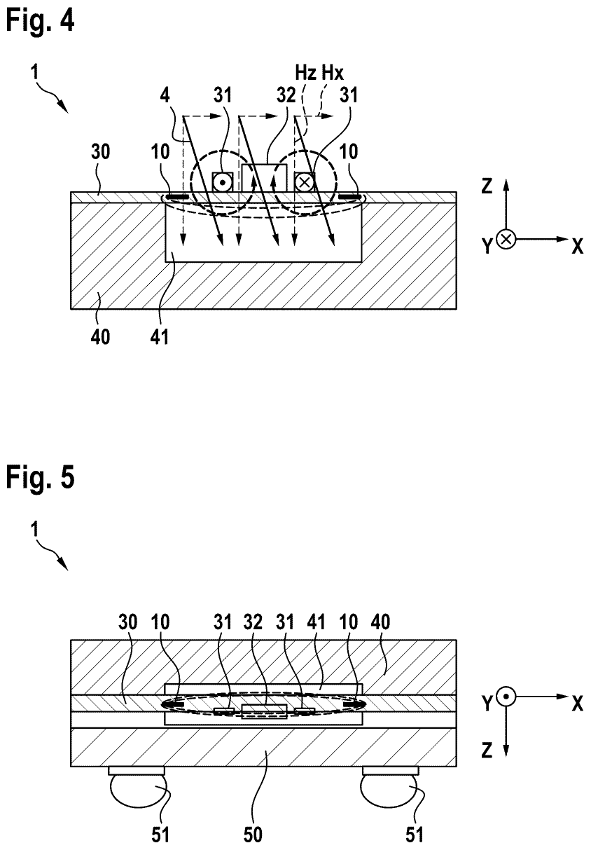

FIG. 4 shows a schematic illustration of a cross-section through a sensor apparatus 1 according to one embodiment. A MEMS structure 30 may be provided on a substrate, for example a MEMS substrate 40 having an opening or cavity 41. One or more sensor devices 10 may be provided on or in this MEMS structure 30. A possible example of an arrangement of these sensor devices 10 will be described in further detail below.

The MEMS structure 30 may also comprise a coil 31. By applying an electric current to the windings of this coil 30, the MEMS structure 30 can be deflected. In this way, tensile or compressive forces can be applied to the sensor devices 10. A ferromagnetic element 32 may additionally be provided, if necessary. This ferromagnetic element 32 may be arranged, for example, inside the coil 31.

FIG. 4 also shows the external magnetic field 4 with the in-plane components Hx and the out-of-plane component Hz.

FIG. 5 shows a schematic illustration of a cross-section through a sensor apparatus 1 according another embodiment. The construction shown in the upper region in FIG. 5 corresponds (in played form) to the construction described above in connection with FIG. 4. Furthermore, the sensor apparatus 1 according to FIG. 5 comprises a substrate 50, for example a silicon substrate, in the lower region. In this way, for example the cavity 41 in the MEMS structure 40 can be closed and thus protected from external influences.

Furthermore, it is also possible to provide an integrated circuit, for example an application-specific integrated circuit (ASIC), in the substrate 50. This circuit may, for example, supply the required voltage VCC to the sensor devices 10. The circuit may also sense and process the voltages between node points K1 and K2. If necessary, this circuit may also control the coil 31. Thus, the deflection of the MEMS structure 30 for applying a desired force to the sensor devices 10 and the evaluation of the resulting signals at the node points K1 and K2 of the sensor devices 10 can be easily synchronized.

For external contacting, suitable contact elements 51 may be provided on the substrate 50.

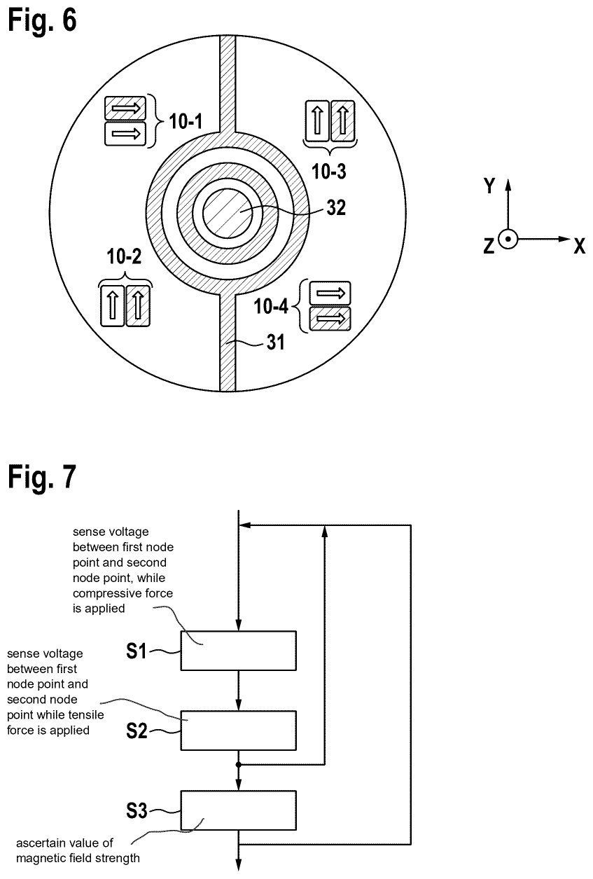

FIG. 6 shows a schematic plan view of a MEMS substrate 30 for a sensor apparatus 1 according to one embodiment. As can be seen in FIG. 6, for example four sensor devices 10-i may be arranged equidistantly, for example at vertices of a virtual square. In this case, for example diagonally opposite sensor devices 10-i may be oriented identically, while each sensor device 10-i is rotated 90 degrees relative to sensor devices which are adjacent along the edges of the virtual square.

In particular, the reference magnetic field directions and the preferred directions of all sensor elements 11-14 may lie in a common plane.

With such an arrangement, it is possible to ascertain the orientation of a magnetic field in all three spatial directions x, y and z. For example, the sensor devices 10-1 and 10-4 may sense magnetic field components in the y and z directions, while the other two sensor devices 10-2 and 10-3 may sense magnetic field components in the x and z directions.

FIG. 7 shows a flowchart which forms the basis of a method for operating a sensor apparatus according to one embodiment. The method may in particular be carried out using one of the sensor apparatuses 1 described above. Accordingly, the statements already made above in connection with FIGS. 1A to 6 apply to the method described below. Analogously, the sensor apparatus 1 described above can also comprise any components that may be required in order to implement the method described below.

### K1K2

In a step S1, a first voltage V1 between the first node point K1 and the second node point K2 of the at least one sensor device 10 is sensed while a compressive force is applied by the microelectromechanical structure 30.

In step S2, a voltage between the first node point K1 and the second node point K2 of the at least one sensor device 10 is sensed while a tensile force is applied by the microelectromechanical structure 30.

After the voltages have been sensed, a value of an external magnetic field strength can be ascertained in step S3. The value of the magnetic field strength may in particular be accomplished using the sensed voltages. Individual values may be ascertained for the individual spatial directions of a three-dimensional space.

The external magnetic field component for the plane which is parallel to the plane spanned by the preferred direction and the reference magnetic field direction (in-plane component) results from the average value of the first voltage V1 and the second voltage V2: (V1+V2)/2. The external magnetic field component perpendicular to this plane results from the difference between the first voltage V1 and the second voltage V2: V1−V2.

In summary, the present invention relates to a sensor element for three-dimensionally sensing a magnetic field by means of magnetoresistive sensor elements. For this purpose, a sensor apparatus is proposed in which at least one arrangement with four magnetoresistive sensor elements in the form of a Wheatstone bridge can be deflected by means of a microelectromechanical structure so that a mechanical force is applied to the sensor elements.

1-10. (canceled)

11. A sensor apparatus, comprising:
at least one sensor device, each sensor device having four magnetoresistive sensor elements; and
a microelectromechanical structure configured to apply a tensile force or compressive force to the sensor elements of the at least one sensor device;
wherein, in each sensor device, a first magnetoresistive sensor element is arranged between a positive voltage supply terminal and a first node point, a second magnetoresistive sensor element is arranged between the first node point and a negative voltage supply terminal, a third magnetoresistive sensor element is arranged between a positive voltage supply terminal and a second node point, and a fourth magnetoresistive sensor element is arranged between the second node point and the negative voltage supply terminal,
wherein reference magnetic field directions of the first, second, third and fourth sensor elements are oriented identically,
wherein preferred directions of the first and fourth sensor elements are oriented oppositely to the preferred directions of the second and fourth sensor elements, and
wherein the reference magnetic field directions and the preferred directions of first, second, third, and fourth sensor elements lie in a common predetermined plane.

12. The sensor apparatus according to claim 11, wherein the at least one sensor device includes multiple sensor devices, wherein a first group of the sensor devices includes at least one sensor device, and a second group of the sensor devices includes at least one sensor device, and wherein the preferred directions of the sensor elements of the first group of sensor devices are oriented perpendicularly to the preferred directions of the second group of sensor devices.

13. The sensor apparatus according to claim 12, wherein the first group of sensor devices comprises two sensor devices and the second group of sensor devices comprises two sensor devices.

14. The sensor apparatus according to claim 11, wherein the microelectromechanical structure includes a coil configured to deflect the microelectromechanical structure with the at least one sensor device in a direction perpendicular to the predetermined plane.

15. The sensor apparatus according to claim 14, wherein the coil includes a ferromagnetic element.

16. The sensor apparatus according to claim 11, further comprising a processing device configured to sense, for each of the at least one sensor device, a voltage between the first node point and the second node point of the sensor device and to ascertain a value of a magnetic field strength using the sensed voltage.

17. The sensor apparatus according to claim 16, wherein the processing device is configured to ascertain individual values of the magnetic field strength for mutually orthogonal spatial directions.

18. The sensor apparatus according to claim 16, wherein the processing device is also configured to control the microelectromechanical structure.

19. The sensor apparatus according to claim 11, wherein the processing device is implemented as an application-specific integrated circuit in the sensor apparatus.

20. A method for operating a sensor apparatus, the sensor apparatus including:
at least one sensor device, each sensor device having four magnetoresistive sensor elements, and
a microelectromechanical structure configured to apply a tensile force or compressive force to the sensor elements of the at least one sensor device,
wherein, in each sensor device, a first magnetoresistive sensor element is arranged between a positive voltage supply terminal and a first node point, a second magnetoresistive sensor element is arranged between the first node point and a negative voltage supply terminal, a third magnetoresistive sensor element is arranged between the positive voltage supply terminal and a second node point, and a fourth magnetoresistive sensor element is arranged between the second node point and the negative voltage supply terminal,
wherein reference magnetic field directions of the first, second, third and fourth sensor elements are oriented identically,
wherein preferred directions of the first and fourth sensor elements are oriented oppositely to the preferred directions of the second and fourth sensor elements, and
wherein the reference magnetic field directions and the preferred directions of first, second, third, and fourth sensor elements lie in a common predetermined plane;
the method comprising the following steps:
sensing a voltage between the first node point and the second node point of the at least one sensor device while a compressive force is applied by the microelectromechanical structure;
sensing a voltage between the first node point and the second node point of the at least one sensor device while a tensile force is applied by the microelectromechanical structure; and
ascertaining a value of a magnetic field strength using the sensed voltages.
